(19) United States
(12) Patent Application Publication
(10) Pub. No.: US 2024/0348010 A1
(43) Pub. Date: Oct. 17, 2024

(54) Cat's-eye swept source laser with chromatic dispersion compensated cavity

(71) Applicant: KineoLabs, Billerica, MA (US)

(72) Inventor: Walid A. Atia, Jamaica Plain, MA (US)

(21) Appl. No.: 18/632,733

(22) Filed: Apr. 11, 2024

Related U.S. Application Data
(60) Provisional application No. 63/495,640, filed on Apr. 12, 2023.

(51) Int. Cl. H01S 5/06; H01S 5/02253; H01S 5/024

(52) U.S. Cl. CPC H01S 5/0607; H01S 5/02253; H01S 5/02415

(57) ABSTRACT

A tunable or swept laser architecture that is appropriate for swept source optical coherence tomography and other applications including spectroscopy employing a cat's-eye configuration with a preferably transmissive tilt tuned interference thin film filter.

### RELATED APPLICATIONS

This application claims the benefit under 35 U.S.C. § 119(e) of U.S. Provisional Application No. 63/495,640, filed on Apr. 12, 2023, which is incorporated herein by reference in its entirety.

### BACKGROUND OF THE INVENTION

Grating tuned semiconductor external cavity lasers generally exhibit good performance with narrow lines and broadband tunability. Such lasers, however, are difficult to align.

The Littrow configuration is a specific setup for grating tuned lasers that provides a simple and compact design. In this configuration, the laser cavity and the diffraction grating are aligned at the same angle, with the laser beam reflecting back on itself.

The Littrow configuration provides several advantages over other grating tuned laser configurations. First, it requires only a single diffraction grating, which simplifies the design and reduces the cost. Second, the alignment of the laser cavity and the grating is fixed, which eliminates the need for mechanical adjustments and improves the stability of the laser.

To tune the laser to a different wavelength, the angle of the grating is adjusted using a piezoelectric transducer, for example. This changes the angle at which the light is diffracted, and therefore changes the wavelength of light that is reflected back into the cavity.

Aligning a Littrow laser can be challenging due to the need for precise alignment between the laser cavity and the diffraction grating. The laser beam must be directed at a precise angle onto the grating to ensure that it is reflected back into the cavity. In addition, the angle of the grating must be adjusted very precisely to tune the laser to a different wavelength. This requires a high degree of accuracy, and any errors in the angle can cause the laser to fail to lase or reduce the efficiency of the laser.

And alternative architecture is an interference filter tuned cat's eye swept laser external cavity. In this configuration, a first, collimating lens is located with its focal point at the exit facet of a gain chip, such that the light from the gain chip is collimated. A second, cat's eye lens, focuses that collimated beam onto mirror defining one end of the laser cavity. In the collimated space between the lenses, and the interference filter is tilt-tuned. In such a configuration, the misalignment sensitivities are greatly reduced.

The use of the cat's-eye laser architecture for optical coherence tomography (OCT) and spectroscopy, for example, has been documented in U.S. patent application Ser. Nos. 18/184,015 and 18/184,019, filed on Mar. 15, 2023 by Atia and Flanders, which applications are incorporated herein by this reference, hereinafter Atia Applications. This is an old architecture that was documented in an article entitled “Interference-filter-tuned alignment-stabilized, semiconductor external-cavity laser,” by Zorabedian and Trutna in Optics Letters, Vo. 13, No. 10, October 1988.

### SUMMARY OF THE INVENTION

Definitionally, tunable laser must function over a range of wavelengths.

A concomitant challenge is chromatic dispersion. This is the phenomenon of different wavelengths of light refracting at different angles when passing through a medium. This can have a significant impact on the focal length of a lens, which is the distance between the lens and its focal point.

When chromatic dispersion occurs in a lens, it causes different wavelengths of light to focus at slightly different distances from the lens. This means that the focal length of the lens is not the same for all wavelengths of light, resulting in chromatic aberration.

In imaging systems, chromatic aberration can cause images to appear blurred or distorted, particularly around the edges of the image. It can also result in color fringing, where different colors appear at different distances from the center of the image.

To correct for chromatic dispersion and reduce chromatic aberration, lenses can be designed with multiple elements made from different types of glass or with special coatings. These elements are designed to refract different wavelengths of light in a way that brings them back into focus at the same point, reducing color fringing and improving image quality.

Chromatic dispersion affects the performance of cat's eye lasers since focal lengths of the collimating and cat's eye lenses cannot be precisely separated from the gain chip front facet and the back mirror/output coupler for all operating wavelengths.

The present invention concerns the replacement of lenses in a cat's eye laser with one or more compound lenses that compensate or minimize chromatic aberration in the cavity.

Preferably the cat's eye lens is made up of two lens elements, a positive lens made from a low dispersion glass such as crown glass, and a negative lens made from a higher dispersion glass such as flint glass. The two elements are preferably cemented together to form a single compound lens. The positive and negative elements refract the different wavelengths of light in opposite directions, which helps to reduce chromatic aberration and improve the quality of the focus on the mirror across the laser's wavelength of operation.

In general, according to one aspect, the invention features a tunable laser, comprising a gain chip for amplifying light in a laser cavity, a collimating lens for collimating light from the gain chip, an end reflector of the laser cavity, an interference bandpass filter between the collimating lens and the end reflector for tuning the wavelength of the light, and a compound lens focusing the collimated light on the end reflector.

The compound lens can include at least two lens elements. These can be a positive lens element made from a low dispersion glass, and a negative lens element made from a higher dispersion glass. The two elements are preferably cemented together to form a single compound lens.

The mirror/output coupler can be concave to further improve the robustness of the laser cavity.

At least one angle control actuator, such as a servomechanism, is used for tilting interference bandpass filter in the laser cavity in the current example.

In general, according to another aspect, the invention features a tunable laser comprising a gain chip for amplifying light in a laser cavity, a collimating lens for collimating light from the gain chip, a concave end reflector of the laser cavity, an interference bandpass filter between the collimating lens and the end reflector for tuning the wavelength of the light, at least one angle control actuator for tilting interference bandpass filter in the laser cavity, and a lens focusing the collimated light on the end reflector.

In general, according to another aspect, the invention features a method for tuning a laser system comprising amplifying light using a gain chip, receiving collimated light from the gain chip by using a compound lens, reflecting light back into the laser's cavity from the compound lens, and providing a passband of light by using a thin film interference bandpass filter between the gain chip and the compound lens.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1A is a schematic side view of a cat's-eye tunable laser according to the present invention;

FIG. 1B is a schematic side view of a cat's-eye tunable laser employing a servo galvanometer;

FIGS. 2A, 2B, and 2C are schematic top views of gain chips for the tunable lasers;

FIG. 3 is a schematic side view of a cat's-eye tunable laser according to a second embodiment;

FIG. 4A is a schematic plot of transmission as a function of frequency showing the passband of the bandpass filter; and

FIG. 4B is a plot of tilt angle as a function of center wavelength for the bandpass filter.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Also, all conjunctions used are to be understood in the most inclusive sense possible. Thus, the word “or” should be understood as having the definition of a logical “or” rather than that of a logical “exclusive or” unless the context clearly necessitates otherwise. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

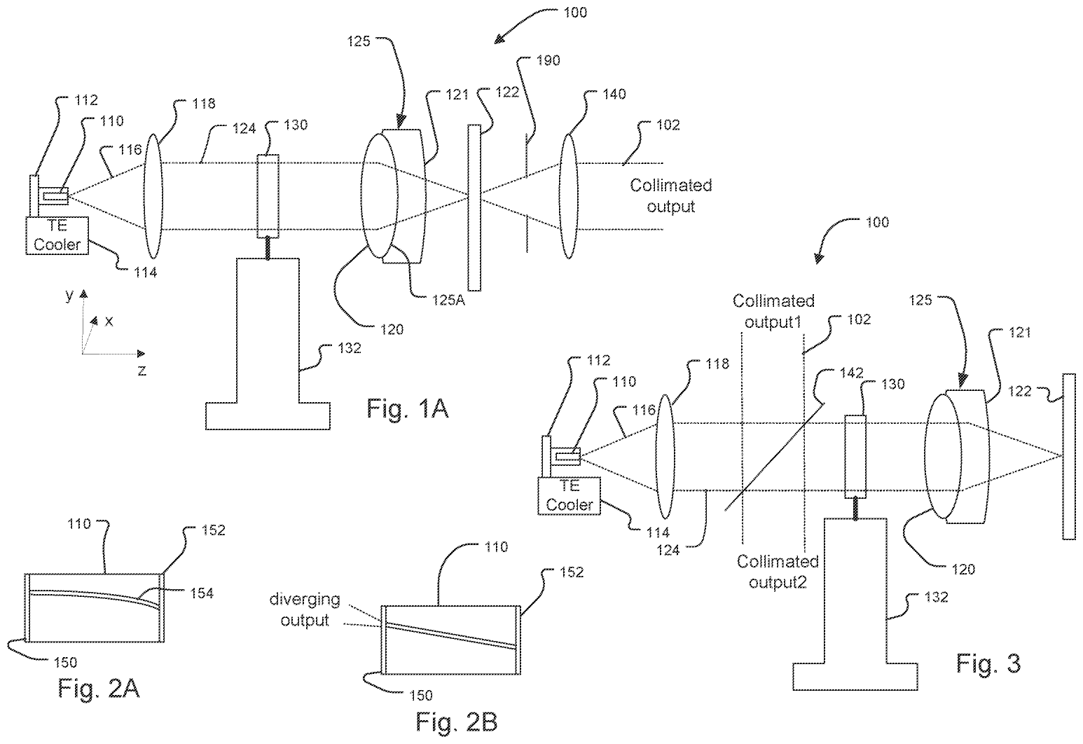

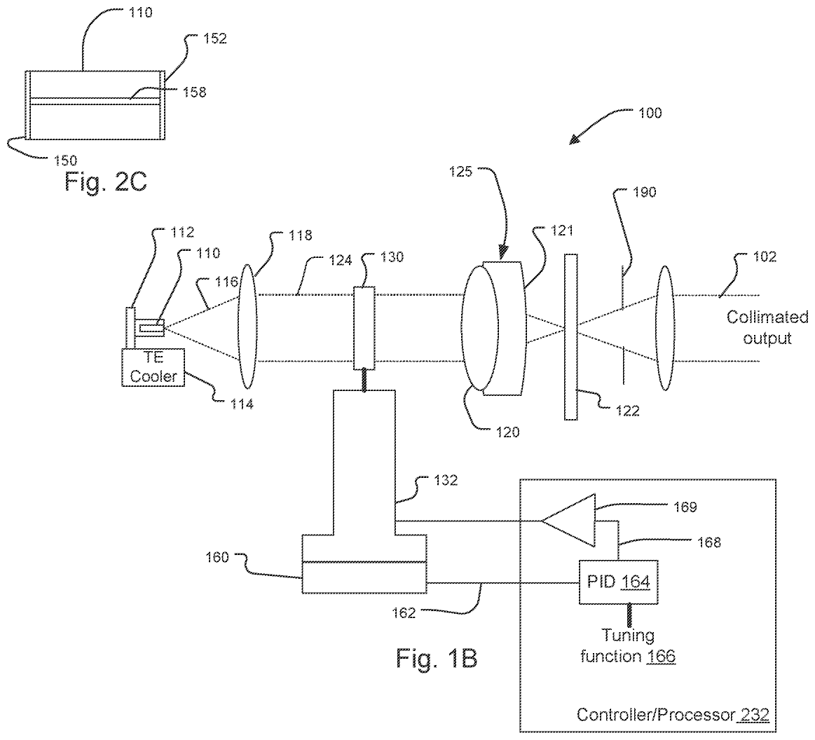

FIG. 1A shows a tunable laser 100 that is sometimes referred to as a cat's-eye laser, which has been constructed according to the principles of the present invention.

The laser's amplification is provided by a GaAlAs gain chip 110, in one example. The gain chip 110 amplifies light in the wavelength range of about 800 to 900 nanometers. Preferably its center wavelength is around 840 nanometers, which is useful for applications such as ophthalmic imaging and other diagnostic uses because of the water window (650 to 950 nm) at these wavelengths. Another advantage of this wavelength range is that it can be detected with standard cameras with silicon-based imager chips. Specifically, the output is detected with silicon, e.g., complementary metal-oxide-semiconductor (CMOS) or charge-coupled device CCD, imagers.

Other material systems can be selected for the gain chip, however, when operation in different bands is required. Common material systems are based on III-V semiconductor materials, including binary materials, such as GaN, GaAs, InP, GaSb, InAs, as well as ternary, quaternary, and pentenary alloys, such as InGaN, InAlGaN, InGaP, AlGaAs, InGaAs, GaInNAs, GaInNAsSb, AlInGaAs, InGaAsP, AlGaAsSb, AlGaInAsSb, AlAsSb, InGaSb, InAsSb, and InGaAsSb. Collectively, these material systems support operating wavelengths from about 400 nanometers (nm) to 2500 nm, including longer wavelength ranges extending into multiple micrometer wavelengths. Semiconductor quantum well, quantum cascade and quantum dot gain regions are typically used to obtain especially wide gain and spectral emission bandwidths, and support operation up to 250 μm in wavelength. Quantum well layers may be purposely strained or unstrained depending on the exact materials and the desired wavelength coverage.

Interrogating these different bands is important for spectrometry systems that analyze different gases with different absorption features in these various bands.

In the preferred current embodiment, the gain chip 110 is mounted in a TO-can type hermetic package 112. This protects the chip 110 from dust and the ambient environment including moisture. In some examples, the TO-can package has an integrated or a separate thermoelectric cooler 114.

The free space beam 116 from the package 112 is diverging in both axes (x, y). It is collimated by a collimating lens 118. The resulting collimated beam is received by a compound focusing lens 125, which focuses the light onto a cat's eye mirror/output coupler 122. This defines the other end of the laser cavity, extending between the mirror/output coupler 122 and the back/reflective facet of the gain chip 110.

The compound lens 125 preferably includes two lens elements, a positive lens element 120 made from a low dispersion glass, and a negative lens element 121 made from a higher dispersion glass. The two elements 120, 121 are preferably cemented together to form a single compound lens along interface 125A between the positively curved rear surface of the lens element 120 and the negatively curved front surface of the negative lens element 121. The positive and negative elements 120, 121 refract the different wavelengths of light within the tuning range of the laser in opposite directions, which helps to reduce chromatic aberration and improve the quality of the focus on the mirror 190 across the laser's wavelength of operation.

The compound lens is typically an achromat lens such as a couplet. Another alternative is an apochromat lens.

Often the back focal length of the compound lens is between 1 millimeter (mm) and 20 mm. Preferably, it is between 3 and 10 mm. The clear aperture is between 1 millimeter (mm) and 20 mm. Preferably, it is between 3 and 10 mm.

The collimated light 124 between the collimating lens 118 and the compound focusing lens 125 passes through a thin film interference bandpass filter 130. This provides a pass band of approximately 0.3 nanometers (nm) full width at half maximum (FWHM). More generally, its pass band is between 0.2 nm and 0.5 nm FWHM, or more generally between 0.1 nm and 2 nm FWHM. Even more generally, it is between 0.05 nm to 5 nm FWHM.

The bandpass filter is held on an arm of an angle control actuator 132 that changes the angle of the bandpass filter 130 to the collimated light 124. In one example, the angle control actuator is a galvanometer. In other examples, the angle control actuator 132 is a servomotor or an electrical motor that continuously spins the bandpass filter 130 in the collimated beam 124. This allows for tilting of the bandpass filter 130 with respect to the collimated beam 124 to thereby tilt-tune the filter and thus change the passband to scan or sweep the wavelength of the swept laser 100. Typically, the angle control actuators tilts the angle of the bandpass filter 130 in a range of less than 60 degrees to the beam to approaching 0 degrees. In most operation, the angle control actuator tilts the bandpass filter between 50 degrees and 10 degrees to the axis of the beam.

Tuning speed specifications for a galvanometer generally range from 0.1 Hz to 50 kHz. For the higher speeds, a 25 kHz resonant galvanometer can be used with bi-directional tuning, but higher and lower speeds can be used. Wavelength tuning speed is usually given in nm/sec, so for a 100 Hz tuning speed ideal for retinal imaging applications where a line-speed camera at 100 kHz will give 1000 sampled bandwidth points and 70 nm tuning range, this would give 70 nm/10 msec=7000 nm/sec. In general, the tuning speed should be between 3,000 nm/sec and 11,000 nm/sec or higher.

For retinal or industrial imaging with low-cost CMOS cameras, 840 nm center wavelength is an ideal water window. The tuning range is usually minimally 30 nm of tuning range. Preferably, the tuning range is closer to 60 nm or 70 nm or more. This provides good resolution of <8 micrometers in air. In general, the tuning range should be between 30 nm and 100 nm.

The size of the collimated beam 124 is important for many applications. As a general rule, a smaller beam results in higher divergence resulting in a larger cone half angle (CHA). This reduces the minimum line width over angle for a tunable filter. In the current embodiment, the collimated beam is preferably not less than, i.e., greater than, 1 millimeter (mm) FWHM and is preferably greater than 2 mm FWHM for retinal OCT application. It can be smaller, however, for many spectroscopy applications in the infrared, visible or ultraviolet. In general, the CHA should be less than 0.04×0.02 degrees and preferably about 0.02×0.01 degrees or less.

The light from the gain chip is polarized. In the common architectures, the polarization is horizontal or parallel to the epitaxial layers of the edge-emitting gain chip 110. In the preferred configuration, the filter is oriented to receive the S polarization in order to maintain narrow line width of the filter as it is tilt tuned. On the other hand, the P polarization broadens drastically at large tilt angles. S polarization has higher loss at larger tilt angles than P. So, the filter design needs to address these issues by providing a low enough loss across the tuning band for S, in the current embodiment.

On the other hand, for spectroscopy, P polarization configurations might be desirable due to the higher powers across the scanband.

In general, the present cat's-eye configuration provides a number of advantages. It provides low loss, low tolerance, repeatable stable operation since it provides for a lower angle wavelength change over grating-based lasers.

The mirror/output coupler 122 will typically reflect about 80% of the light back into the laser's cavity and transmit about 20% of light. More generally, the mirror/output coupler can reflect from 10% to 99% of light (transmitting 90% to 1%, respectively), depending on the output power and laser cavity loss desired. Higher reflectivity results in lower loss cavities and thus wider laser tuning range where gain exceeds loss, but results in lower output power. In typical operation, the mirror/output coupler 122 reflects less than 90%.

In some embodiments, the mirror/output coupler 122 is concave to further improve the robustness of the laser cavity. See, e.g., “Adjustment-free cat's eye cavity He-Ne laser and its outstanding stability,” Zhiguang Xu, Shulian Zhang, Yan Li, and Wenhua Du, Optics Express Vol. 13, Issue 14, pp. 5565-5573 (2005), doi.org/10.1364/OPEX.13.005565. In this configuration, the focal length of the compound lens 125, the radius of curvature of the concave mirror/output coupler 122, and the distance between the two elements are all equal. The concave mirror often has a spherical or parabolic curvature. The normal incident paraxial beam will be reflected back. Even for the obliquely incident paraxial beam, the concave mirror/output coupler 122 provides high parallelism for the incident and the reflected beams.

The reflectivity of the mirror/output coupler 122 is preferably provided by a dielectric interference coating. The construction of partially or fully reflecting dielectric coatings on the coupler involves depositing a series of alternating layers of high and low refractive index materials onto the substrate. The number, thickness, and refractive index of each layer are carefully chosen to create a multilayer stack that reflects a specific portion of the incident light while transmitting the rest.

In some embodiments, an iris or mask 190 is added typically after the mirror output coupler 122 to clip the beam edge. This reduces power fluctuations as the beam wanders due to refraction in the tilting bandpass filter 130. Preferably, it is between 80% and 95% and preferably about 90% of the beam size.

Typically, the diverging beam from the mirror output coupler 122 is typically collimated with an output collimating lens 140 to form a free space output beam 102.

In other embodiments, a second compound lens such as an achromat lens or apochromat lens is used in place of the collimating lens 118.

FIG. 1B shows a preferred implementation of the tunable laser 100 and specifically the angle control actuator 132.

The angle control actuator 132 is operated as a servomechanism. In the illustrated embodiment, the angle control actuator 132 is a servo controlled galvanometer with an encoder 160. The encoder 160 produces an angle signal 162 indicating the angle of the galvanometer and thus the filter 130 to the collimated beam 124. Preferably, the encoder is an optical encoder and is often analog.

A controller/processor receives the angle signal 162 at a PID (proportional-integral-derivative) controller 164. The PID controller 164 compares the angle signal 164 to a specified tuning function. Often this is sawtooth or triangular waveform. The PID controller 166 produces the control function 168 that is used to drive the windings of the galvanometer 132 via an amplifier 169.

FIG. 2A shows a preferred gain chip architecture. This chip 110 is termed a single angled facet (SAF) edge-emitting chip. As such, it has a high reflectivity (HR) coated rear facet 150. It has an antireflective (AR) coated front facet 152. In addition, for improved performance, it has a curved ridge waveguide 154 that is perpendicular to the rear facet 150 but is angled at the interface with the front facet 152. This angling at the front facet along with the AR coating reduces reflections at the front facet reflectivity by up to 40 dB and significantly improves laser performance by reducing parasitic reflections that can otherwise lead to non-smooth tuning and mode-hopping.

FIG. 2B shows another potential edge emitting gain chip configuration. The basic configuration is termed a semiconductor optical amplifier (SOA) gain chip. As such, it has an AR coated rear facet and an AR coated front facet. Its straight but angled ridge waveguide 156 intersects with the facets at an angle to minimize reflections back into the chip. In one example, its back facet light is coupled to a lens or pair of lenses and a mirror which reflects light to return through the lens and to the chip. The mirror could be made partially reflecting to take the output out from the back facet.

FIG. 2C shows another potential gain chip configuration. The basic configuration is termed a Fabry-Perot gain chip. As such, it has an HR coated rear facet 150 and an AR coated front facet 152. The straight ridge waveguide 158 intersects with the front facet 152 at a perpendicular angle and thus does create some internal reflections that can affect performance.

FIG. 3 shows another example of the laser 100. Here the one or more outputs are taken within the laser's cavity. Specifically, an angled beam splitter 142 picks off part of the light in the laser's cavity as collimated output beams output1 and output2. The end mirror 122 has typically high reflectivity, such as higher than 99%, unless it is used to provide a third output. Here also, in some examples, the mirror/output coupler 122 is concave to further improve the robustness of the laser cavity, with the focal length of the compound lens 125, the radius of curvature of the concave mirror 122, and the distance between the two elements all being equal.

As discussed, the output coupler is often implemented as a beam splitter. The output coupling is then chosen by selecting an output coupler with the desired ratio of reflectivity versus transmissivity. Another option is to use the combination of a polarization beam splitter and a quarter waveplate. This allows for adjustability in the output coupling by controlling the angle of the quarter waveplate.

In this configuration, there are actually two outputs: collimated output1 and collimated output2. Generally, collimated output1 will provide higher power since it receives light directly from the chip. This output is also characterized by a higher amplified spontaneous emission (ASE) spectra. On the other hand, collimated output2 will exhibit a lower higher power, but this output is characterized by a lower spectral sideband since it takes light after double passing through the bandpass filter. Note also that in this configuration the output light's position does not deviate while the filter angle is tuned because the light is reflected back through the filter and retraces itself.

In this example, an integrated k clock is possible. An etalon is added in one output. A trigger signal is then created that a camera can use for efficient sampling without the need for software resampling.

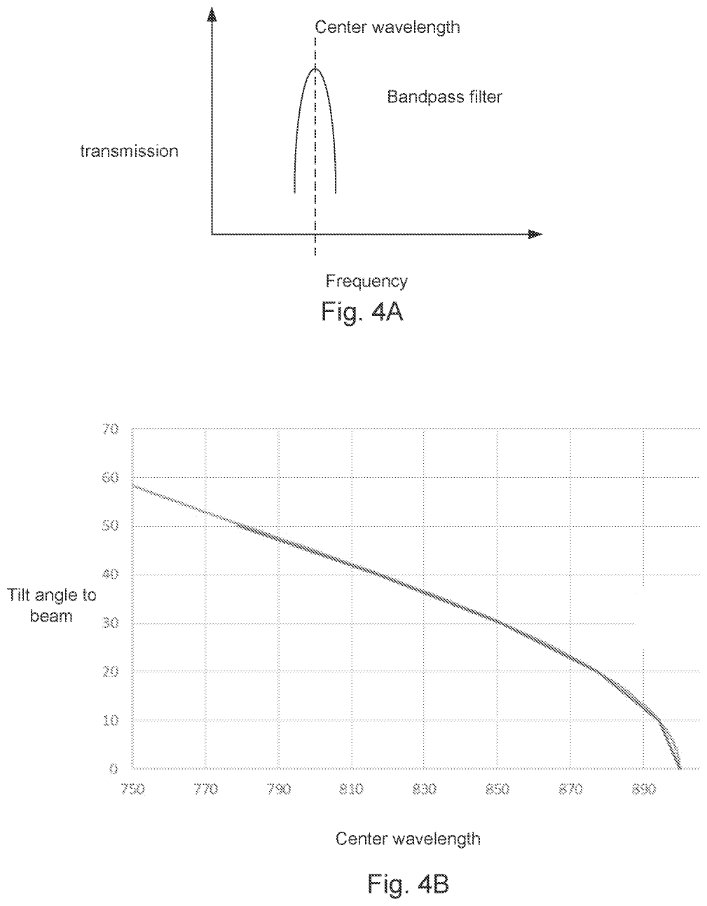

The collimated light between the collimating lens and the cat's eye focusing lens FIG. 4A is a plot of transmission as a function of frequency for the passband filter at a specified angle. It shows the narrow passband.

FIG. 4B is a plot of angle of the filter 130 to the beam as a function of the passband wavelength for S polarization. It shows how the passband can be tuned by the galvanometer tilting of the passband filter.

The following formula relates the passband wavelength as a function of the center wavelength with no tilt, and θ, which is the angle between the beam and the filter.

$${λ}_{θ} = {λ}_{o} \sqrt{1 - {( \frac{{n}_{o}}{{n}_{eff}} sin θ )}^{2}}$$

The forgoing formula shows how the filter exhibits a slow tilt angle at low angles then gets faster. Operation is preferable in the more linear region to minimize the required tilt angle and have a more linear scan. The illustrated filter function is for a laser operating in the 810-870 nm tuning range. So 900 nm is chosen for 0 degree incidence wavelength. Thus, it will have the smallest operating angle around 870 nm and tune from 810-870 nm. Note that angle tuning always reduces the wavelength. N_{eff} is adjustable and can be helpful to amplify the tuning with angle.

The presenting disclosed lasers are often employed in optical coherence tomography systems and spectrometry systems as detailed in the incorporated Atia Applications.

While this invention has been particularly shown and described with references to preferred embodiments thereof, it will be understood by those skilled in the art that various changes in form and details may be made therein without departing from the scope of the invention encompassed by the appended claims.

What is claimed is:

1. A tunable laser, comprising:
a gain chip for amplifying light in a laser cavity;
a collimating lens for collimating light from the gain chip;
an end reflector of the laser cavity;
an interference bandpass filter between the collimating lens and the end reflector for tuning the wavelength of the light; and
a compound lens focusing the collimated light on the end reflector.

2. The tunable laser of claim 1, wherein the compound lens includes at least two lens elements.

3. The tunable laser of claim 2, wherein the compound lens includes a positive lens element made from a low dispersion glass, and a negative lens element made from a higher dispersion glass.

4. The tunable laser of claim 3, wherein the two elements are cemented together to form a single compound lens.

5. The tunable laser of claim 3, wherein the mirror/output coupler is concave to further improve the robustness of the laser cavity.

6. The tunable laser of claim 1, further comprising at least one angle control actuator for tilting interference bandpass filter in the laser cavity.

7. The tunable laser of claim 6, wherein the at least one angle control actuator is a servomechanism.

8. The tunable laser of claim 6, wherein the at least one angle control actuator is a galvanometer or a motor that continuously spins the thin film bandpass filter.

9. The tunable laser of claim 1, wherein a diameter of the collimated light is greater than 1 millimeter (mm).

10. The tunable laser of claim 1, wherein a diameter of the collimated light is greater than 2 mm.

11. A tunable laser, comprising:
a gain chip for amplifying light in a laser cavity;
a collimating lens for collimating light from the gain chip;
a concave end reflector of the laser cavity;
an interference bandpass filter between the collimating lens and the end reflector for tuning the wavelength of the light;
at least one angle control actuator for tilting interference bandpass filter in the laser cavity; and
a lens focusing the collimated light on the end reflector.

12. The tunable laser of claim 11, wherein the at least one angle control actuator is a galvanometer.

13. The tunable laser of claim 11, wherein the at least one angle control actuator is a servomechanism.

14. The tunable laser of claim 11, wherein a diameter of the collimated light is greater than 1 millimeter (mm).

15. The tunable laser of claim 11, wherein a diameter of the collimated light is greater than 2 mm.

16. A method for tuning a laser system, comprising:
amplifying light using a gain chip;
receiving collimated light from the gain chip by using a compound lens;
reflecting light back into the laser's cavity from the compound lens; and providing a passband of light by using a thin film interference bandpass filter between the gain chip and the compound lens.
